(19) United States
(12) Patent Application Publication
(10) Pub. No.: US 2025/0321922 A1
(43) Pub. Date: Oct. 16, 2025

(54) Networks-On-Chip For Configuration And Emulation Of Integrated Circuits

(71) Applicant: Altera Corporation, San Jose, CA (US)

(72) Inventors: Scott Weber, Piedmont, CA (US); Jun Pin Tan, Kuala Lumpur (MY); Rajiv Kumar, George Town (MY); Kiun Kiet Jong, George Town (MY); Yi Peng, Newark, CA (US); Tara Shirvaikar, San Francisco, CA (US)

(73) Assignee: Altera Corporation, San Jose, CA (US)

(21) Appl. No.: 19/253,252

(22) Filed: Jun. 27, 2025

(51) Int. Cl. G06F 15/78; G06F 30/3308; G06F 30/343

(52) U.S. Cl. CPC G06F 15/7825; G06F 15/7871; G06F 30/3308; G06F 30/343

(57) ABSTRACT

An integrated circuit includes logic circuits and a network-on-chip in a region of the integrated circuit. The network-on-chip is configurable to transmit at least two of user data, configuration data, and emulation data to the logic circuits. The network-on-chip is configurable to transmit the user data to and from the logic circuits during a user mode of the integrated circuit. The network-on-chip is configurable to transmit the configuration data to the logic circuits for configuring the logic circuits during a configuration mode of the integrated circuit. The network-on-chip is configurable to transmit the emulation data to and from the logic circuits during an emulation mode of the integrated circuit.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data containing configuration bits. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can be used for application acceleration tasks in a datacenter and can be reprogrammed during datacenter operation to perform different tasks.

### BRIEF DESCRIPTION OF DRAWINGS

FIG. 1 is a diagram that depicts an example of an integrated circuit (IC) that includes micro networks-on-chip (NOCs) in a central fabric region of the IC.

FIG. 2 is a diagram that illustrates response buffer circuits, micro networks-on-chip (NOCs), and a local configuration manager (LCM) with respect to a network-on-chip (NOC) bridge and circuitry in the fabric region of the IC of FIG. 1.

FIG. 3 is a diagram that illustrates examples of micro NOCs that are configurable to transmit information in an integrated circuit (IC) during a configuration mode or an emulation mode.

FIG. 4 is a diagram that illustrates examples of micro networks-on-chip (NOCs) for configuration and emulation tasks that span multiple integrated circuit (IC) dice.

FIG. 5 is a diagram that illustrates an example of a micro network-on-chip (NOC) controller (MNC) circuit that can be located in any of the micro NOCs disclosed herein.

FIG. 6 is a diagram that illustrates micro NOCs coupled to local configuration manager (LCM) circuits, a security controller (SC) circuit, target bridges (TNIU), an initiator bridge (INIU), and a configuration network-on-chip (CNOC).

FIG. 7 is a diagram that illustrates micro NOCs, local configuration manager (LCM) circuits, a security controller (SC) circuit, target bridges (TNIU), initiator bridges (INIU), an interface circuit, and a configuration network-on-chip (CNOC).

FIG. 8 is a diagram that illustrates examples of circuits that can be used for readback and writeback operations during an emulation mode in an integrated circuit (IC).

FIG. 9 is a diagram of an illustrative example of a configurable integrated circuit (IC).

FIG. 10A illustrates a block diagram of a system that can be used to implement a circuit design to be programmed into a programmable logic device using design software.

FIG. 10B is a diagram that depicts an example of a programmable logic device that includes fabric dies and base dies that are connected to one another via microbumps.

FIG. 11 is a block diagram illustrating a computing system configured to implement one or more aspects of the embodiments described herein.

### DETAILED DESCRIPTION

Some types of configurable integrated circuits (ICs) include configuration networks-on-chip (CNOCs) and local sector managers (LSMs) that are used to configure the ICs. In such a configurable integrated circuit (IC), the IC can be configured by sending configuration data through the configuration networks-on-chip (CNOCs) in the IC to the local sector managers (LSMs) in the IC. However, configuring a configurable IC through CNOCs may require a substantial amount of runtime due to the limited bandwidth of the CNOCs.

According to some examples disclosed herein, a micro network-on-chip (NOC) in an IC can be used to perform configuration and emulation operations in the IC, including fabric configuration, reconfiguration, partial reconfiguration, and emulation in the IC. Using the micro NOC to perform these functions reduces the runtime of configuration and emulation operations by an order of magnitude or more compared to previously known solutions. In some examples, one or more micro NOCs in the IC are decoupled from response buffer circuits and are instead coupled to local configuration managers (LCMs). The LCMs send and receive information over the micro NOCs to and from security controller circuits (SCCs). The LCMs use the micro NOCs to send and receive information to and from configuration memory controller circuits to perform the configuration and emulation operations.

The micro network-on-chip (NOC) is configurable to transmit two or more of user data, configuration data, and/or emulation data to logic circuits in a central (fabric) region of the IC. As used herein, configuration data refers to data that is used to configure configurable logic circuits in an IC during a configuration mode of the IC. As used herein, user data refers to data that is transmitted to and from logic circuits in an integrated circuit during a user mode (i.e., normal operation) of the integrated circuit in order to implement the intended functions of the IC.

Emulation of an application specific integrated circuit (ASIC), as well as ASIC prototyping, are two applications of a field programmable gate array (FPGA) configurable IC, where a circuit design for an ASIC is mapped to an FPGA. The circuit behavior of the circuit design is exercised on the FPGA in a similar way to circuit simulation using a software simulator. The emulation on an FPGA is significantly faster than software simulation. The emulation speed can be, for example, in the range of tens of megahertz. The prototype is intended to evaluate the performance of an ASIC in a real world environment where input/output signals (IOs) operate at speed. The prototype speed is in the range of hundreds of megahertz. The circuit design under prototype is scaled down from the real world environment of gigahertz (GHz). The readback and writeback operations are the same for emulation and prototyping applications.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

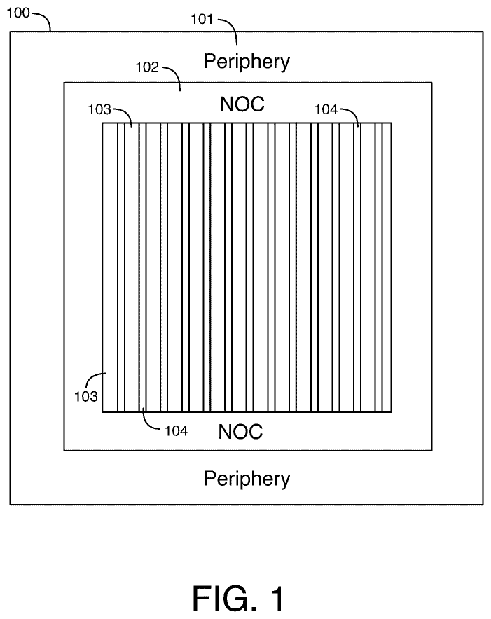

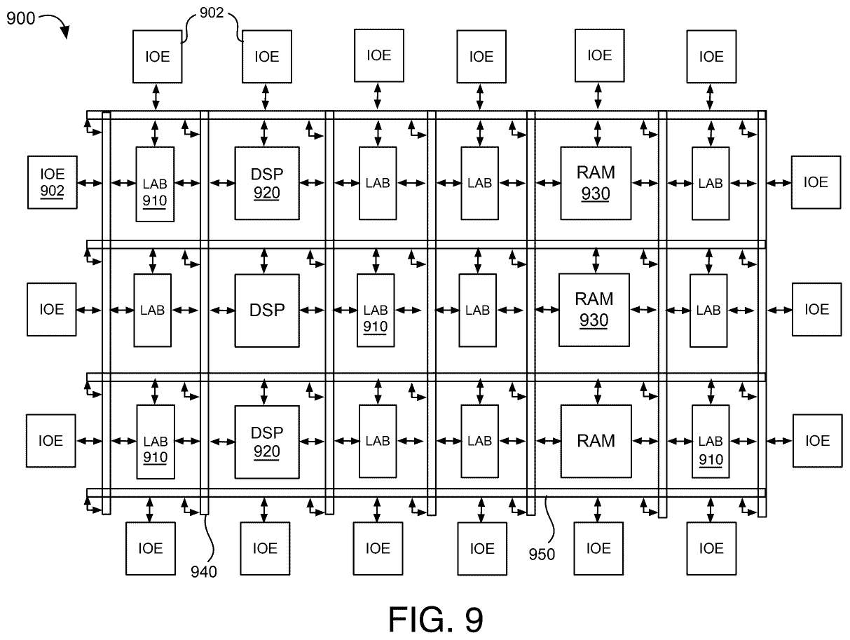

FIG. 1 is a diagram that depicts an example of an integrated circuit (IC) 100 that includes micro networks-on-chip (i.e., micro NOCs) 104 in a central fabric region 103 of the IC 100. The central fabric region 103 is also referred to herein as central region or fabric region 103. FIG. 1 shows 13 micro NOCs 104 as an example. According to various examples, ICs can include any number of the micro NOCs disclosed herein. The fabric region 103 includes soft logic and memory circuits that are not shown in FIG. 1, but are shown, for example, in FIG. 9 and other figures herein.

IC 100 also includes a periphery region 101 and a network-on-chip (NOC) 102 that surrounds the fabric region 103 and is inside the periphery region 101. The IC 100 of Figure (FIG. 1 can be any type of integrated circuit (IC), such as a configurable IC (e.g., a field programmable gate array (FPGA) or programmable logic device (PLD), a microprocessor IC, a graphics processing unit IC, a memory IC, an application specific IC, a transceiver IC, a memory IC, etc.

The micro NOCs 104 are high-bandwidth hardened data paths between the NOC 102 and the fabric region 103. Each of the micro NOCs 104 extends across the entire length of the fabric region 103 as shown in FIG. 1. The micro NOCs 104 allow data traffic on the NOC 102 to be forwarded deep into the fabric region 103 by leveraging available routing tracks over fabric memory circuits (e.g., block random access memory or BRAM) along with the fabric memory circuits to couple an interface to collections of ports of the fabric memory circuits. The fabric memory circuits are used as buffers that support micro NOCs 104 being utilized for hardened memory transport between external and on-chip memory circuits, effectively allowing each micro NOC 104 to enable ubiquitous NOC ports. The micro NOCs 104 also support ubiquitous interface bridge creation throughout the fabric region 103, effectively allowing the BRAMs to be NOC-attached memory. This interface may be, for example, Advanced Extensible Interface Memory-Mapped (AXI-MM) interface. In some implementations, the micro NOCs 104 allow efficient use of resources in the fabric region 103 by avoiding routing congestion, because the micro NOCs 104 can operate at a higher frequency (e.g., twice the frequency) than the circuitry in the surrounding fabric region 103.

If data is transmitted through the micro NOCs 104 at a greater frequency than the frequency of the logic circuits in the fabric region 103, the micro NOC 104 interface can use a double-pumping/double-wide interface to match the different frequencies. A response buffer (RB) circuit replaces a fabric bridge in the micro NOC 104 to redirect the data traffic from a NOC to the micro NOC 104. As an example, one RB circuit can feed two micro NOCs 104, as disclosed herein below. As other examples, an RB circuit can couple to an N number of micro NOCs 104, where N is any positive integer. The micro NOCs 104 can maintain the bandwidth of data, while a fabric bridge and/or fabric routing provide less bandwidth (e.g., ⅛^{th} the bandwidth) to the fabric target. As an example, when a device is 8 sectors wide, the full data bandwidth of peripheral memories can be transmitted by a micro NOC 104 and provided to the fabric target. Any efficiency loss on the micro NOC 104 caused by a small sharing of channels on the micro NOC 104 is typically small.

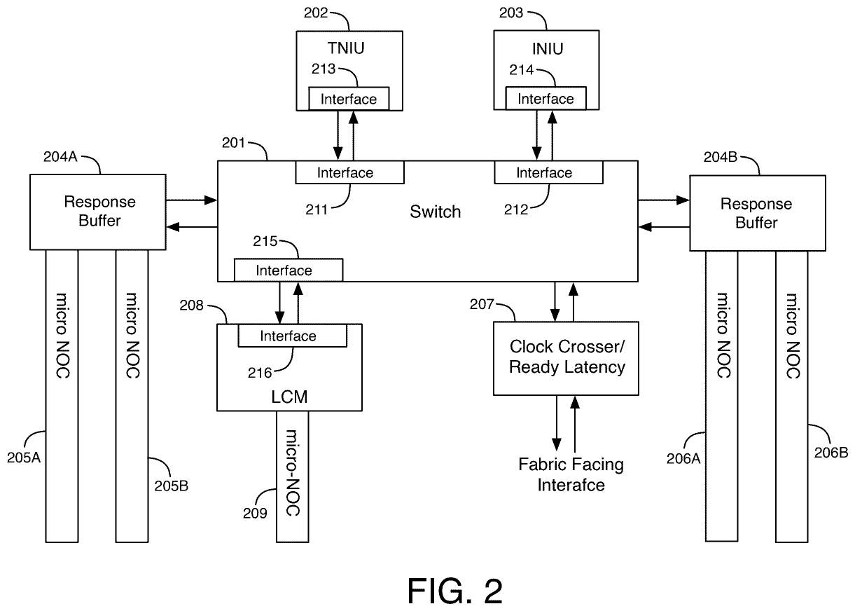

FIG. 2 is a diagram that illustrates response buffer circuits, micro networks-on-chip (micro NOCs), and a local configuration manager (LCM) circuit in IC 100 with respect to a network-on-chip (NOC) bridge and circuitry in the fabric region 103 of IC 100. Figure (FIG. 2 illustrates a target bridge (TNIU) 202 and an initiator bridge (INIU) 203, both of which are bridges to the NOC 102. FIG. 2 also shows a switch circuit 201, two response buffer circuits 204A-204B, 5 micro networks-on-chip (NOCs) 205A-205B, 206A-206B, and 209, and clock crosser/ready latency circuitry 207. Micro NOCs 205A-205B, 206A-206B, and 209 are examples of the micro NOCs 104 of FIG. 1. TNIU 202 and/or INIU 203 can transmit signals indicating data between the NOC 102 and switch circuit 201. As used herein, the term “data” refers to user data as well as other values, such as control signal values (e.g., commands and requests).

Switch circuit 201 can transmit data between the response buffer circuits 204A-204B and the NOC 102 via the TNIU 202 and/or INIU 203. The response buffer circuit 204A can exchange data between the switch circuit 201 and circuitry in the fabric region 103 through micro NOCs 205A-205B. The response buffer circuit 204B can exchange data between the switch circuit 201 and circuitry in the fabric region 103 through micro NOCs 206A-206B. Switch circuit 201 can route data traffic from multiple response buffer circuits 204A-204B to the fabric region 103 via micro NOCs 205A-205B and 206A-206B. Thus, data can be exchanged between NOC 102 and circuitry in the fabric region 103 of IC 100 through TNIU 202 and/or INIU 203, switch circuit 201, response buffer circuits 204A and/or 204B, and micro NOCs 205A, 205B, 206A, and/or 206B. Data can also be exchanged between NOC 102 and circuitry in the fabric region 103 of IC 100 through TNIU 202 and/or INIU 203, switch circuit 201, the clock crosser/ready latency circuitry 207, and a fabric facing interface, as shown in FIG. 2.

FIG. 2 also illustrates a local configuration manager (LCM) circuit 208 coupled to the micro NOC 209 and to switch circuit 201. The LCM circuits disclosed herein, including LCM circuit 208, can be controller circuits configured to route data (including commands and requests) to and from sources and sinks in fabric region 103 via the micro NOCs, such as micro NOC 209. In some examples, IC 100 can be a configurable IC that is put into a configuration mode to configure configurable logic circuits in the fabric region 103. The IC 100 can also, in other examples, be put in an emulation mode to perform emulation functions related to emulating a circuit design for another IC. In response to the IC 100 being in a configuration mode or in an emulation mode, switch circuit 201 decouples response buffer circuits 204A-204B and micro NOCs 205A-205B and 206A-206B from sending and receiving data traffic to and from NOC 102 via switch circuit 201, TNIU 202, and INIU 203.

The micro NOC 209 is configurable to transmit user data during a user mode of the IC, configuration data during the configuration mode, and/or emulation data during the emulation mode to logic circuits in the fabric region of the IC. In response to the IC 100 being in a configuration mode, a user mode, or in an emulation mode, switch circuit 201 couples LCM circuit 208 and micro NOC 209 to send and receive data traffic to and from NOC 102 via switch circuit 201, TNIU 202, and INIU 203. In order to send data through LCM circuit 208 and micro-NOC 209 during configuration mode, user mode, or emulation mode, LCM circuit 208 is a target for TNIU 202 on the NOC 102. When an address for a TNIU transaction matches the LCM circuit 208 address space, the data traffic for that TNIU transaction is targeted for the LCM circuit 208. The LCM circuit 208 intercepts, interprets, and converts the data traffic into commands to be sent or received to or from a configuration manager circuit via the micro NOC 209. The LCM circuit 208 selects one of multiple configuration manager (CM) circuits in micro NOC 209 as the destination for the data traffic and indicates the destination CM circuit in the commands sent through the NOC 209.

Data traffic, addresses, and/or commands received from the configuration manager circuit are transmitted via micro NOC 209 to LCM circuit 208, and then from LCM circuit 208 through switch 201 and INIU 203 to NOC 102. The commands used by the LCM circuit 208 can be different than the commands used by the response buffer circuits 204A-204B. The micro NOC provides the physical transport layer.

The data traffic, addresses, and/or commands can be transmitted between TNIU 202 and switch 201 through interface 213 in TNIU 202 and interface 211 in switch 201. The data traffic, addresses, and/or commands can be transmitted through INIU 203 and switch 201 through interface 214 in INIU 203 and interface 212 in switch 201. The data traffic, addresses, and/or commands can be transmitted between switch 201 and LCM circuit 208 through interface 216 in LCM circuit 208 and interface 215 in switch 201. LCM circuit 208 can exchange the data traffic, addresses, and/or commands with a configuration manager circuit through the micro NOC 209 (e.g., one of micro NOCs 104). The data traffic, addresses, and/or commands can be part of configuration data, user data, and/or emulation data transmitted to and/or from logic circuits in the fabric region of the IC.

In some examples, fabric region 103 in IC 100 is partitioned into an array of sectors. Each sector has one or more configuration manager (CM) circuits and an LCM circuit that manages the CM circuits in the sector. The LCM and CM circuits are coupled through the micro NOCs 104. The CM circuits include control logic circuitry that can read from and write to configurable memory circuits in fabric region 103 (e.g., configuration random access memory (CRAM), lookup table random access memory (LUTRAM), embedded random access memory (ERAM), and other types of RAM) as well as user registers. ERAM is RAM that resides in the fabric region 103, such as static RAM. Each LCM circuit includes logic circuitry that can process data before sending the data (including commands) to the CM circuits and logic circuitry that can process the data (including commands) received from the CM circuits.

In addition, a CRAM single-event upset (SEU) error detection feature can utilize the micro NOCs 104 and 209. The CM circuits can report SEU errors to the LCM circuit 208 via micro NOC 209. The LCM circuit 208 and the CM circuits can perform SEU error injection via micro NOC 209.

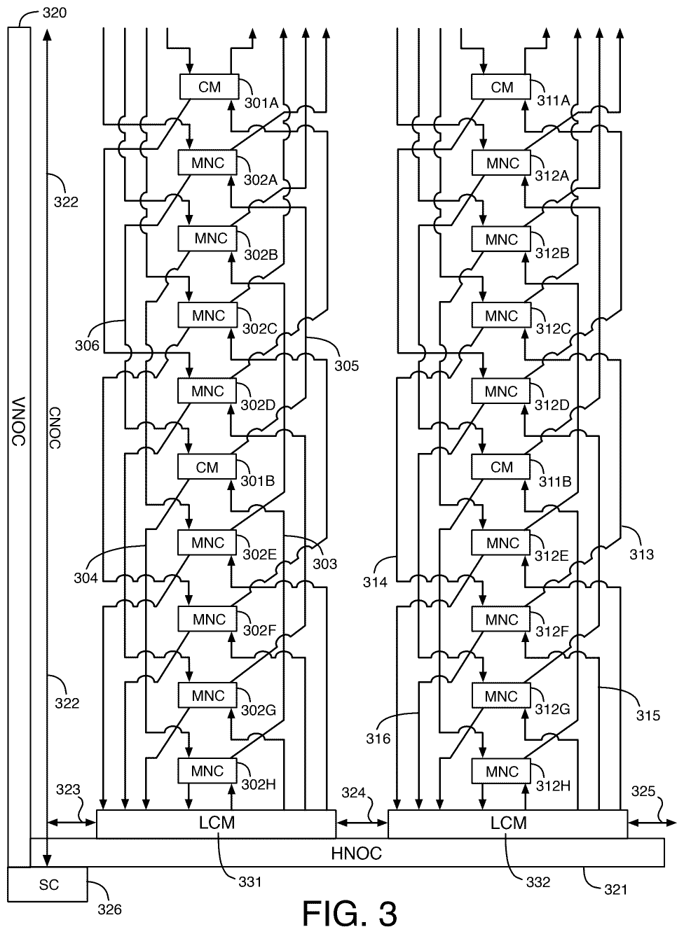

FIG. 3 is a diagram that illustrates examples of two micro NOCs that are configurable to transmit information in an integrated circuit (IC) during a configuration mode or an emulation mode. FIG. 3 illustrates a vertical network-on-chip (VNOC) 320, a horizontal network-on-chip (HNOC) 321, configuration networks-on-chip (CNOCs) 322-325, and a security controller (SC) circuit 326 in an IC such as IC 100. Configuration data for configuration of configurable logic circuits in fabric region 103 during the configuration mode or information for performing emulation during emulation mode can be transmitted through VNOC 320, HNOC 321, and/or CNOCs 322-325 to the security controller (SC) circuit 326.

SC circuit 326 performs authentication, validation, encryption, decryption, and/or other security functions on the configuration data and/or other information received via VNOC 320, HNOC 321, and/or CNOCs 322-325 to generate secured information (e.g., validated, authenticated, encrypted, and/or decrypted information). SC circuit 326 then transmits the secured information that has been output by the security functions (e.g., validated, authenticated, encrypted, and/or decrypted information) through HNOC 321 and/or CNOCs 322-325 to local configuration manager (LCM) circuits 331-332. The LCM circuits 331-332 can also perform authentication, validation, encryption, decryption, etc. for configuration and emulation data.

In the example of FIG. 3, the first micro NOC includes configuration manager (CM) circuits 301A and 301B and micro NOC controller (MNC) circuits 302A-302H that are coupled together through various busses, such as busses 303, 304, 305, and 306. The first micro NOC is configurable to transmit user data, configuration data, and/or emulation data to logic circuits in the fabric region of the IC. The CM circuits 301A-301B are configured to perform configuration and/or emulation operations. The first micro NOC is coupled to the local configuration manager (LCM) circuit 331. Configuration data, user data, and/or emulation data can be transmitted between LCM circuit 331 and MNC circuits 302E-302H through various busses as shown in FIG. 3. The configuration data, user data, and/or emulation data can be transmitted between the MNC circuits 302A-302H and the CM circuits 301A-301B through various other busses. In FIG. 3, the busses are shown as lines with arrows that indicate the directions of signal flows through the busses. As examples, data can be transmitted through bus 306 from MNC circuit 302A to CM circuit 301B, data can be transmitted through bus 303 from MNC circuit 302H to CM circuit 301B, data can be transmitted through bus 305 from CM circuit 301B to MNC circuit 302A, and data can be transmitted through bus 304 from CM circuit 301B to MNC circuit 302H.

In the example of FIG. 3, the second micro NOC includes configuration manager (CM) circuits 311A and 311B and micro NOC controller (MNC) circuits 312A-312H that are coupled together through various busses, such as busses 313, 314, 315, and 316. The second micro NOC is configurable to transmit user data, configuration data, and/or emulation data to logic circuits in the fabric region of the IC. The CM circuits 311A-311B are configured to perform configuration and/or emulation operations. The second micro NOC is coupled to local configuration manager (LCM) circuit 332. Configuration data, user data, and/or emulation can be transmitted between LCM circuit 332 and MNC circuits 312E-312H through various busses as shown in FIG. 3. The configuration data, user data, and/or emulation data can be transmitted between MNC circuits 312A-312H and CM circuits 311A-311B through various other busses. In FIG. 3, these busses are shown as lines with arrows that indicate the directions of signal flows through the busses. As examples, data can be transmitted through bus 314 from MNC circuit 312C to MNC circuit 312F, data can be transmitted through bus 313 from MNC circuit 312F to MNC circuit 312C, data can be transmitted through bus 316 from MNC circuit 312F to LCM circuit 332, and data can be transmitted through bus 315 from LCM circuit 332 to MNC circuit 312F.

Each one of the configuration manager (CM) circuits 301A-301B and 311A-311B can, for example, be configured to function as a source in the micro NOC that receives data from one or more memory circuits in fabric region 103 and then transmits the data through the micro NOC to the LCM circuit. Each one of the CM circuits 301A-301B and 311A-311B can also be configured to function as a sink in the micro NOC that receives data from the LCM circuit through the micro NOC and then provides the data to one or more memory circuits in fabric region 103. Each of the micro NOCs of FIG. 3 can have one or more sources and/or one more sinks. Each of the micro NOCs of FIG. 3 is configurable to place each one of the sources in the micro NOC that receives data from one or more memory circuits at one of multiple locations in the micro NOC. Each of the micro NOCs of FIG. 3 is also configurable to place each one of the sinks in the micro NOC that provides data to one or more memory circuits at one of the multiple locations in the micro NOC.

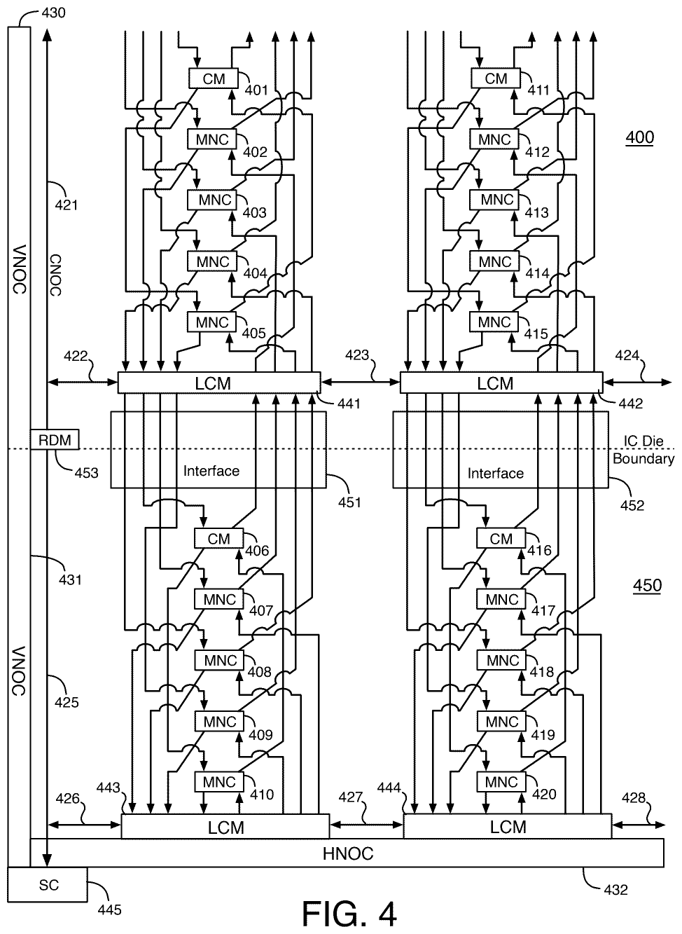

FIG. 4 is a diagram that illustrates examples of micro networks-on-chip (NOCs) for configuration and emulation operations that span multiple integrated circuit (IC) dice 400 and 450. The first IC die 400 of FIG. 4 includes vertical network-on-chip (VNOC) 430, configuration networks-on-chip (CNOCs) 421-424, local configuration manager (LCM) circuits 441-442, remote device manager (RDM) 453, and first and second micro networks-on-chip (NOCs) that are coupled as shown in FIG. 4. The first micro NOC includes configuration manager (CM) circuit 401 and micro NOC controller (MNC) circuits 402-405. The second micro NOC includes CM circuit 411 and MNC circuits 412-415. The first micro NOC is coupled to LCM circuit 441, and the second micro NOC is coupled to LCM circuit 442 through busses shown as lines with arrows in FIG. 4. The first and second micro NOCs are configurable to transmit user data, configuration data, and/or emulation data to logic circuits in the central (fabric) region of the IC. MNC circuits 402-405 are coupled to exchange user data, configuration data, and/or emulation data with LCM circuit 441, and CM circuit 401 is coupled to exchange user data, configuration data, and/or emulation data with MNC circuit 405. MNC circuits 412-415 are coupled to exchange user data, configuration data, and/or emulation data with LCM circuit 442, and CM circuit 411 is coupled to exchange user data, configuration data, and/or emulation data with MNC circuit 415.

The second IC die 450 includes VNOC 431, CNOCs 425-428, horizontal network-on-chip (HNOC) 432, LCM circuits 443-444, a security controller (SC) circuit 445, and third and fourth micro networks-on-chip (NOCs) that are coupled as shown in FIG. 4. The third micro NOC includes configuration manager (CM) circuit 406 and micro NOC controller (MNC) circuits 407-410. The fourth micro NOC includes CM circuit 416 and MNC circuits 417-420. The third micro NOC is coupled to LCM circuit 443, and the fourth micro NOC is coupled to LCM circuit 444 through busses shown as lines with arrows in FIG. 4. MNC circuits 407-410 are coupled to exchange user data, configuration data, and/or emulation data with LCM circuit 443, and CM circuit 406 is coupled to exchange user data, configuration data, and/or emulation data with MNC circuit 410. MNC circuits 417-420 are coupled to exchange user data, configuration data, and/or emulation data with LCM circuit 444, and CM circuit 416 is coupled to exchange user data, configuration data, and/or emulation data with MNC circuit 420.

FIG. 4 also shows interface circuits 451 and 452 that couple together IC dies 400 and 450. Interfaces 451-452 in FIG. 4 can, for example, represent input/output circuits in both IC dies and external conductors, such as micro bumps and/or conductors in interposers, package substrates, connection bridges etc.

In the example of FIG. 4, SC circuit 445 performs data security functions (e.g., validation, authentication, and decryption) on input data, as discussed above with respect to SC circuit 326, to generate data traffic as an output. SC circuit 445 delivers the data traffic to the LCM circuits 443-444 through the HNOC 432. If the data traffic is for the local IC die 450, the data traffic is provided through the third and/or fourth micro NOCs to CM circuits 406 and/or 416 (or other CM circuits in the micro NOCs) for configuration or emulation operations.

If the data traffic generated by SC circuit 445 is not for the local IC die 450, the SC circuit 445 transmits the data traffic to the next IC die 400. The data traffic can be transmitted from SC circuit 445 to IC die 400 through HNOC 432, LCM circuits 443 and/or 444, the third micro NOC and/or the fourth micro NOC, and interface 451 and/or interface 452 to LCM circuits 441 and/or 442, respectively. The LCM circuits 441 and/or 442 determine if the data traffic is intended for transmission to IC die 400 or to the next IC die (e.g., another IC die in the same integrated circuit package or system). If the data traffic is for the local IC die 400, the data traffic is provided from LCM circuits 441 and/or 442 through the first and/or second micro NOCs to CM circuits 401 and/or 411 (or other CM circuits in the micro NOCs) for configuration or emulation operations. The organization of IC dies disclosed herein with respect to FIG. 4 allows for IC dies to be coupled in this manner with data traffic coordinated by a single SC circuit 445. The RDM circuit 453 manages die-to-die traffic through the CNOCs 421 and 425.

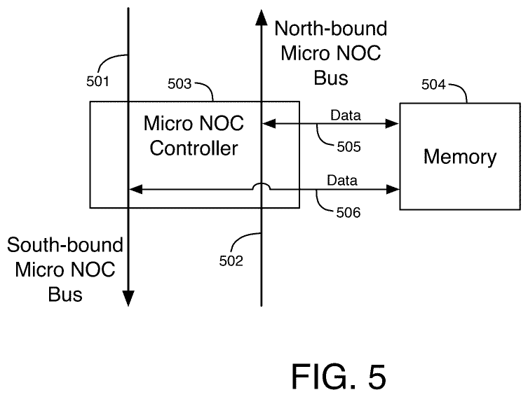

FIG. 5 is a diagram that illustrates an example of a micro network-on-chip (NOC) controller (MNC) circuit 503 that can be located in any of the micro NOCs disclosed herein. The micro NOC controller (MNC) circuit 503 is configured to exchange data with a memory circuit 504 in fabric region 103. Memory circuit 504 can be, as an example, a configuration random access memory (CRAM) used for storing configuration data for configuring configurable logic circuits in fabric region 103. As another example, memory circuit 504 can be an embedded random access memory (ERAM) for storing readback or writeback data during an emulation mode of the IC. As yet another example, memory circuit 504 can be a lookup table random access memory (LUTRAM).

Micro NOC controller circuit 503 is configured to transmit data received from an LCM circuit or another MNC circuit through a south-bound micro NOC bus 501 in the micro NOC to memory circuit 504 through a bus 506. Micro NOC controller circuit 503 is also configured to receive data from memory circuit 504 through bus 506 and to transmit the data received from memory circuit 504 through south-bound micro NOC bus 501 to an LCM circuit or another MNC circuit in the micro NOC.

Micro NOC controller circuit 503 is also configured to transmit data received from an LCM circuit or another MNC circuit through a north-bound micro NOC bus 502 in the micro NOC to memory circuit 504 through a bus 505. Micro NOC controller circuit 503 is also configured to receive data from memory circuit 504 through bus 505 and to transmit the data received from memory circuit 504 through north-bound micro NOC bus 502 to an LCM circuit or another MNC circuit in the micro NOC. The micro NOC controller circuit 503 of FIG. 5 can be, as examples, in one or more of the micro NOCs disclosed herein with respect to the other figures in a fabric region of an IC.

According to some examples, any of the micro NOCs disclosed herein can have multiple micro NOC controller (MNC) circuits 503 along the length of a single micro NOC. In these examples, the micro NOC has access to embedded fabric memory circuits in the fabric region 103 of the IC 100 through the micro NOC controller circuits 503 in the micro NOC. A micro NOC can, e.g., have one micro NOC controller circuit 503 for each fabric memory circuit that the micro NOC has access to. As discussed above, each micro NOC controller circuit 503 can transport data to and from the micro NOC and a fabric memory circuit. Micro NOC controller circuit 503 can also back-pressure if a BRAM is full or if the micro NOC controller circuit 503 is not allowed to push data to a bus in the micro NOC. Micro NOC controller circuit 503 also locally keeps track of all credits to ensure fair bandwidth allocation for the BRAM groups along the micro NOC.

In the examples of FIGS. 3-4, the NOC paths including the busses from the SC circuits to the LCM circuits are available and configured before the configurable logic circuits in fabric region 103 are configured using configuration data. Thus, the fabric region bridges are appropriately isolated from the fabric region 103. Additionally, bridge shims may be in the process of being configured, while the configuration data for the fabric region 103 is being streamed to the fabric region 103. Thus, all bridges, other than the bridges involved in the configuration process, are appropriately isolated when configuration of the fabric region 103 occurs.

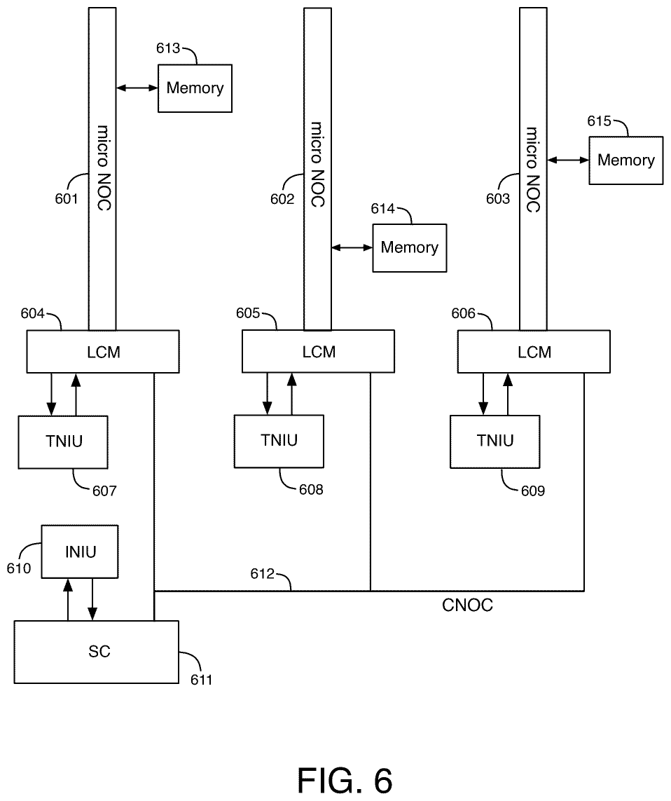

Referring to FIG. 4, the LCM circuits in the base IC die and in a remote IC die send credits to SC circuit 445 via the CNOCs 421 and 425 to indicate input buffer availability. Each LCM circuit is, for example, provided with an Advanced Extensible Interface Memory Mapped (AXI-MM) interface address range. SC circuit 445 indicates the target LCM circuit by specifying the corresponding AXI-MM address range. The configuration and re-configuration flow is disclosed herein below with respect to FIG. 6.

FIG. 6 is a diagram that illustrates an example of a portion of IC 100 that includes three micro NOCs 601-603 coupled to three local configuration manager (LCM) circuits 604-606, a security controller (SC) circuit 611, target bridges (TNIU) 607-609, initiator bridge (INIU) 610, a configuration network-on-chip (CNOC) 612, and memory circuits 613-615. Memory circuits 613, 614, and 615 can be, as examples, LUTRAM, CRAM, and/or ERAM.

Three micro NOCs 601-603 and three LCM circuits 604-606 are shown in FIG. 6 as an example. The architecture of FIG. 6 can be extended to an N-number of micro NOCs and LCM circuits, where N is any positive integer. The IC can also include an HNOC (not shown) that is coupled to the INIU 610 and TNIUs 607-609 and can transmit information between these bridges. The micro NOCs 601-603 are configurable to transmit user data, configuration data, and/or emulation data to logic circuits (e.g., memory circuits) in fabric region 103 of the IC 100. An example of a process having 11 operations is described below for transmitting a configuration data bitstream through the micro NOCs 601-603.

In operation 1, the SC circuit 611 receives and buffers the configuration data bitstream. Operations 2-11 described below may be repeated to complete the configuration and/or re-configuration of configurable logic circuits in fabric region 103. The operations 2-11 described below can be run in parallel to maintain end-to-end crediting.

In operation 2, SC circuit 611 communicates via CNOC 612 to the target LCM circuits 604, 605, and/or 606 to prepare for configuration and/or re-configuration. In operation 3, the target LCM circuits 604, 605, and/or 606 receive messaging sent over CNOC 612 to prepare for configuration and/or re-configuration.

In operation 4, the target LCM circuits 604, 605, and/or 606 respond with credits transmitted back to the SC circuit 611 for flow control indicating the availability of buffering in the LCM circuits 604, 605, and/or 606 for receiving the configuration data bitstream. In operation 5, the SC circuit 611 receives the credits for each of the target LCM circuits 604, 605, and/or 606. Operations 6-11 described below can be repeated to consume all the credits.

In operation 6, SC circuit 611 sends the configuration data bitstream received on the initiator bridge 610 (e.g., an AXI-MM bridge) using a write request (e.g., a AW/W write request according to Advanced Extensible Interface (AXI)) to perform a write operation using a write address (e.g., an AWADDR write address) to target the target bridges 607-609 (e.g., AXI-MM bridges) for the LCM circuits 604-606 and using any appropriate burst type. This transmission is an emulation of streaming.

In operation 7, the target LCM circuits 604, 605, and/or 606 receive the write request AW/W on the target bridges 607, 608, and 609. In operation 8, the target LCM circuits 604, 605, and/or 606 interpret the write data WDATA for the commands that are part of the write request and run the configuration data bitstream through the Datapath Crypto Block (DCB) (e.g., in the LCM circuits) to create packets to target the configuration manger (CM) circuits in the micro NOCs 601-603. The configuration data bitstream received by the LCM circuits is processed by the DCB to generate an output. The output of the DCB is provided through the micro NOCs to the CM circuits in the micro NOCs. The DCB is responsible for performing integrity checks, decryption, and decompression on the incoming configuration data bitstream. The decompression function performed by the DCB expands the incoming configuration data bitstream and produces a high data rate.

In operation 9, the target bridges 607, 608, and/or 609 (e.g., AXI-MM bridges) return a write response B for the write operation. In operation 10, the initiator bridge 610 (e.g., an AXI-MM bridge) receives the write response B. In operation 11, the target CM circuits in micro NOCs 601-603 receive commands from the LCM circuits 604-606 and perform write operations to write the configuration data bitstream to memory circuits 613-615, respectively, (e.g., CRAM or LUTRAM) in fabric region 103.

Because of the crediting and buffering in the SC circuit 611, the write response B can be issued at the time the transaction is processed by the LCM circuit, rather than waiting for the write to propagate to the CM circuit. Error handling occurs over the CNOC 612.

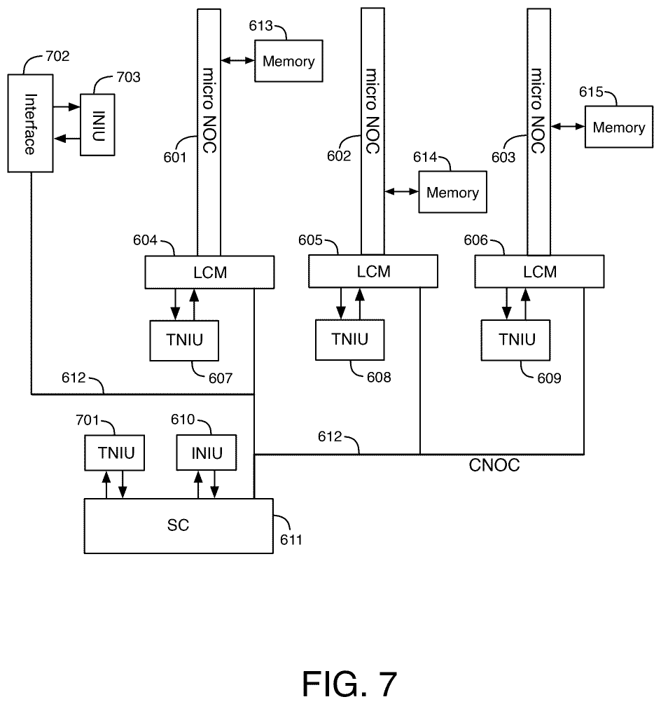

FIG. 7 is a diagram that illustrates another example of a portion of IC 100 that includes three micro NOCs 601-603, three local configuration manager (LCM) circuits 604-606, security controller (SC) circuit 611, target bridges (TNIU) 607-609 and 701, initiator bridges (INIU) 610 and 703, interface circuit 702, configuration network-on-chip (CNOC) 612, and memory circuits 613-615. Three micro NOCs 601-603 and three LCM circuits 604-606 are shown in FIG. 7 as an example. Although the architecture shown in FIG. 7 can be extended to an N-number of micro NOCs and LCM circuits, where N is any positive integer. The micro NOCs 601-603 are configurable to transmit user data, configuration data, and/or emulation data to logic circuits (e.g., memory circuits) in fabric region 103 of the IC 100. The IC 100 also includes an HNOC (not shown) coupled to the INIUs 610 and 703 and to the TNIUs 607-609 and 701. The HNOC can transmit information between these bridges.

IC 100 can include soft logic and/or hard logic that implements interface circuit 702 as an interface to an external computer expansion bus, such as Peripheral Component Interconnect Express (PCIe). The interface circuit 702 (e.g., a PCIe interface) can communicate with SC circuit 611 over CNOC 612, for configuration and re-configuration operations. Interface circuit 702 can be configured with a physical function (PF) dedicated to configuration. Traffic for the configuration PF can be split by the interface circuit 702 to the initiator bridge 703 and then transmitted through CNOC 612 to the SC circuit 611.

According to an exemplary implementation of the circuitry of FIG. 7, a Configuration via Protocol (CVP) flow can be used for initial configuration of configurable logic circuits in IC 100 by configuring a direct memory access (DMA) controller circuit within the interface circuit 702 to read a configuration data bitstream from memory and transport the bitstream to SC circuit 611 for configuration. An example of a process having 19 operations is described below for transmitting a configuration data bitstream through the micro NOCs 601-603 during CvP.

In operation 1, the SC circuit 611 sends configuration data for configuring the DMA controller circuit in interface circuit 702 through the CNOC 612 to enable CVP. In operation 2, the DMA controller circuit in interface circuit 702 communicates over the CNOC 612 to the SC circuit 611 to indicate when the DMA controller circuit is ready for CVP. Operations 3-19 described below can, for example, run in parallel to maintain end-to-end crediting.

In operation 3, the SC circuit 611 transmits credits to interface circuit 702 via the CNOC 612 based on available storage. In operation 4, the DMA controller circuit receives the credits from the SC circuit 611. In operation 5, a configuration data bitstream for configuring configurable logic circuits in fabric region 103 is received from a host by the DMA controller circuit in interface circuit 702.

In operation 6, the initiator bridge 703 (e.g., a PCIe AXI-MM bridge) transmits the configuration data bitstream using a write request in a write data channel (e.g., a AW/W write request according to Advanced Extensible Interface (AXI)). In operation 7, the target bridge 701 (e.g., an AXI-MM bridge) for the SC circuit 611 receives the write request in the write data channel AW/W. In operation 8, the target bridge 701 for the SC circuit 611 sends the write response (e.g., a B write response according to AXI). In operation 9, the initiator bridge 703 receives the write response B. In operation 10, the SC circuit 611 communicates via CNOC 612 to one or more target LCM circuits 604-606 to prepare for configuration and/or re-configuration operations.

In operation 11, the one or more target LCM circuits 604-606 receive messaging transmitted through CNOC 612 indicating to prepare for configuration and/or re-configuration operations. In operation 12, the one or more target LCM circuits 604-606 respond back with credits sent to the SC circuit 611 for flow control indicating the availability of buffering in the one or more target LCM circuits 604-606 for receiving the configuration data bitstream. In operation 13, the SC circuit 611 receives the credits for each LCM circuit 604-606. In operation 14, the SC circuit 611 transmits the configuration data bitstream through initiator bridge 610 using a write request in a write data channel AW/W and using a write address AWADDR to target to the target bridges 607-609 (e.g., AXI-MM bridges) and using any appropriate burst type. This transmission is an emulation of streaming.

In operation 15, the one or more target LCM circuits 604-606 receive the write request in the write data channel AW/W on the target bridges 607-609 (e.g., AXI-MM bridges). In operation 16, the one or more target LCM circuits 604-606 interpret the write data WDATA for the commands and run the configuration data bitstream through the Datapath Crypto Block (DCB) to create packets to target the configuration manger (CM) circuits in the micro NOCs 601-603. In operation 17, the target bridges 607-609 return the write response B. In operation 18, the initiator bridge 610 receives the write response B. In operation 19, the one or more target CM circuits in one or more of the micro NOCs 601-603 receive commands from the LCM circuits 604-606 and perform write operations to write the configuration data bitstream to memory circuits 613-615, respectively, (e.g., CRAM) in the fabric region 103.

To implement partial reconfiguration of configurable logic circuits in fabric region 103 of IC 100, partial reconfiguration data is sent from the SC circuit 611 to the LCM circuits 604-606 via the HNOC. During partial reconfiguration, a read-modify-write operation is performed between the LCM circuits 604-606 and the configuration manager (CM) circuits. Partial reconfiguration can be performed when other traffic is transmitting on the HNOC. During partial reconfiguration, partial reconfiguration data can only be sent to selected ones of the LCM circuits that service the partial reconfiguration regions being reconfigured.

An example of a process having 13 operations is described below for transmitting a partial reconfiguration (PR) data bitstream through the micro NOCs 601-603. These 13 operations refer to the circuitry shown in FIG. 6 as an example.

In operation 1, the SC circuit 611 receives and buffers the PR data bitstream. The remaining operations 2-13 can be repeated to complete the partial reconfiguration. The operations 2-13 described below can be run in parallel to maintain end-to-end crediting.

In operation 2, SC circuit 611 communicates via CNOC 612 to one or more target LCM circuits 604-606 to prepare for partial reconfiguration. In operation 3, the one or more target LCM circuits 604-606 receive the messaging transmitted through CNOC 612 to prepare for partial reconfiguration. In operation 4, the one or more target LCM circuits 604-606 respond with credits sent back to the SC circuit 611 for flow control indicating the availability of buffering in the one or more target LCM circuits 604-606 for receiving the bitstream. In operation 5, SC circuit 611 receives the credits for each LCM circuit 604-606. The operations 6-11 described below can be repeated to consume all of the credits.

In operation 6, the SC circuit 611 transmits the PR data bitstream on the initiator bridge 610 using a write request (e.g., a AW/W write request according to AXI) to perform a write operation on a write channel and using a write address (e.g., an AWADDR AXI write address) to target to the target bridges 607-609 (e.g., AXI-MM bridges) for the LCM circuits 604-606 using any appropriate burst type. This transmission is an emulation of streaming.

In operation 7, the one or more target LCM circuits 604-606 receive the write request AW/W on the target bridges 607-609. In operation 8, the one or more target LCM circuits 604, 605, and/or 606 interpret the write data WDATA for the commands that are part of the write request and run the PR data bitstream through the Datapath Crypto Block (DCB) to create packets to target the configuration manger (CM) circuits in the micro NOCs 601-603, respectively.

In operation 9, the target bridges 607, 608, and/or 609 (e.g., AXI-MM bridges) return a write response B for the write operation. In operation 10, the initiator bridge 610 (e.g., an AXI-MM bridge) receives the write response B. In operation 11, the target CM circuits in micro NOCs 601-603 receive commands from LCM circuits 604-606 and perform read operations to read data from memory circuits 613-615 (e.g., CRAM), respectively, in fabric region 103. In operation 12, the one or more target LCM circuits 604-606 receive the data read from memory circuits 613-615, respectively, during the read operations and perform one or more read-modify operations. In operation 13, the target CM circuits in micro NOCs 601-603 receive commands from LCM circuits 604-606 and perform write operations to write the PR data bitstream to memory circuits 613-615, respectively, in fabric region 103.

Writing partial reconfiguration (PR) data to ERAM can be performed using the configuration data operations described above with respect to FIG. 6, because writing PR data to ERAM does not use read-modify-write operations. Because of the crediting and buffering in the SC circuit 611, the write response B can be issued at the time the transaction is received by the LCM circuits 604-606, rather than waiting for the write signals to propagate to the CM circuits. Error handling can occur over the CNOC 612.

Partial reconfiguration of configurable logic circuits in fabric region 103 of IC 100 can also be performed using the interface circuit 702 of FIG. 7. The operations to perform partial reconfiguration can use Configuration via Protocol (CVP) as described above by having a controller circuit (e.g., a PCIe controller) in interface circuit 702 accept a partial reconfiguration data bitstream and transport the partial reconfiguration data bitstream to SC circuit 611 for partial reconfiguration. An example of a process having 21 operations is described below for transmitting a partial reconfiguration (PR) data bitstream through the micro NOCs 601-603 during CvP.

In operation 1, the SC circuit 611 sends configuration data for configuring the controller circuit in interface circuit 702 through the CNOC 612 to enable CVP. In operation 2, the controller circuit in interface circuit 702 communicates over the CNOC 612 to the SC circuit 611 to indicate when the controller circuit is ready for CVP. Operations 3-21 described below can, for example, run in parallel to maintain end-to-end crediting.

In operation 3, the SC circuit 611 transmits credits to interface circuit 702 via the CNOC 612 based on available storage. In operation 4, the controller circuit receives the credits from the SC circuit 611. In operation 5, a partial reconfiguration (PR) data bitstream for reconfiguring configurable logic circuits in fabric region 103 is received from a host by the controller circuit in interface circuit 702.

In operation 6, initiator bridge 703 (e.g., a PCIe AXI-MM bridge) transmits the PR data bitstream using a write request in a write data channel (e.g., a AW/W write request according to AXI). In operation 7, the target bridge 701 (e.g., an AXI-MM bridge) for the SC circuit 611 receives the write request in the write data channel AW/W. In operation 8, the target bridge 701 for the SC circuit 611 sends the write response (e.g., a B write response according to AXI). In operation 9, the initiator bridge 703 receives the write response B. In operation 10, SC circuit 611 communicates via CNOC 612 to one or more target LCM circuits 604-606 to prepare for partial reconfiguration operations.

In operation 11, the one or more target LCM circuits 604-606 receive messaging transmitted through CNOC 612 indicating to prepare for partial reconfiguration operations. In operation 12, the one or more target LCM circuits 604-606 respond back with credits sent to the SC circuit 611 for flow control indicating the availability of buffering in the one or more target LCM circuits 604-606 for receiving the PR data bitstream. In operation 13, the SC circuit 611 receives the credits for each LCM circuit 604-606. In operation 14, the SC circuit 611 transmits the PR data bitstream on the initiator bridge 610 using a write request in a write data channel AW/W and using a write address AWADDR to target to the target bridges 607-609 (e.g., AXI-MM bridges) and using any appropriate burst type. This transmission is an emulation of streaming.

In operation 15, the one or more target LCM circuits 604-606 receive the write request in the write data channel AW/W on the target bridges 607-609. In operation 16, the one or more target LCM circuits 604-606 interpret the write data WDATA for the commands and run the PR data bitstream through the Datapath Crypto Block (DCB) to create packets to target the configuration manger (CM) circuits in the micro NOCs 601-603. In operation 17, the target bridges 607-609 return a write response B. In operation 18, the initiator bridge 610 receives the write response B.

In operation 19, each target CM circuit in one of the micro NOCs 601-603 receives commands from the LCM circuit in the same micro NOC and performs a read operation to read data from a respective one of memory circuits 613-615 (e.g., CRAM). In operation 20, the one or more target LCM circuits 604-606 receive the data read from memory circuits 613-615 via micro NOCs 601-603, respectively, during the read operations and perform read-modify operations. In operation 21, the one or more target CM circuits in one or more of the micro NOCs 601-603 receive commands from the LCM circuits 604-606 and perform write operations to write the PR data bitstream to memory circuits 613-615, respectively, in the fabric region 103.

During the emulation mode, a micro NOC in IC 100 can be used for readback and writeback operations for emulation and prototyping. The readback and writeback operations can be initiated by a micro NOC initiator, where the data for the readback and writeback operations can be processed and transmitted to external interfaces. During a readback operation, the CM circuits, the micro NOCs, and the LCM circuits are used to offload state information from fabric region 103. The state information is then transmitted from the LCM circuits to fabric region 103 through the micro NOCs as a read operation from the initiator to the LCM circuit target. A writeback operation of the state of IC 100 uses the reverse path, writing through the micro NOC to the LCM circuit.

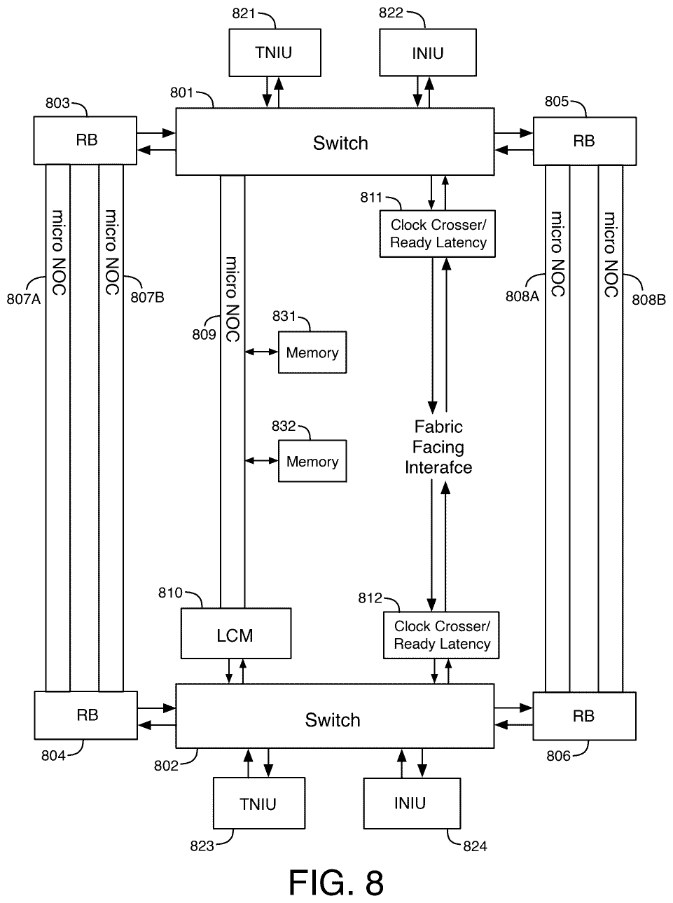

FIG. 8 is a diagram that illustrates examples of circuits that can be used for readback and writeback operations during an emulation mode in an integrated circuit (IC). The circuitry shown in FIG. 8 includes switch circuits 801-802, response buffer circuits 803-806, a local configuration manager (LCM) circuit 810, target (TNIU) bridges 821 and 823, initiator bridges 822 and 824, clock crosser and ready latency circuits 811-812, memory circuits 831-832, and micro networks-on-chip (micro NOCs) 807A-807B, 808A-808B, and 809. Micro NOC 809 is coupled between switch circuit 801 and LCM circuit 810. Micro NOC 809 is configurable to transmit user data, configuration data, and/or emulation data to logic circuits (e.g., memory circuits) in the fabric region of the IC. LCM circuit 810 can communicate with switch circuit 802 through one or more busses. The clock crosser and ready latency circuits 811 and 812 communicate with switch circuits 801 and 802, respectively, and with a fabric facing interface. The circuitry of FIG. 8 can, for example, be located in fabric region 103 of IC 100.

In some implementations, multiple initiators in fabric region 103 (e.g., one per LCM circuit) can be used during readback and writeback operations. According to a specific example for performing readback operations in emulation mode, a readback logic circuit in fabric region 103 can use a fabric region or micro NOC initiator to send individual commands to the LCM circuit targets that prepare for the coordination of readback operations of design under test (DUT) state holder circuits in fabric region 103, including for example, an adaptive logic module (ALM) flip-flop (FF), a lookup table random access memory (LUTRAM), and an embedded random access memory (ERAM). ALM FFs, LUTRAMs, and ERAMs are also collectively referred to herein as DUT state holder circuits. The readback data protocol (e.g., AXI-MM) initiator performs read operations from the target LCM circuit 810 after the command setups. These commands can be interleaved, if desired. AXI-MM responses can be used for flow control of the commands and data movement during the writeback and readback operations.

An example of a process having 35 operations for performing readback for a sector column during emulation mode in an IC is described below. The initiators of the readback can be logic circuitry in fabric region 103 or micro NOC initiators. Multiple initiators can be used to improve performance.

In operation 1, a user triggers a readback operation using a readback logic circuit. Operations 2-34 described below can occur multiple times with the ability to change the ordering of the readback operations to the DUT state holder circuits, e.g., ALM FF, LUTRAM, and ERAM. In operation 2, the readback logic circuit transmits a readback command AXI-MM initiator write request AW/W to LCM circuit 810 to initiate a readback from a first DUT state holder circuit (e.g., an adaptive logic module (ALM) flip-flop (FF)) in fabric region 103. The write request can include operation arguments to select specific units of the DUT state holder circuit. In operation 3, the LCM AXI-MM target bridge 823 receives the write request AW/W. In operation 4, LCM circuit 810 interprets the command in the write data WDATA and begins coordination of readback of the first DUT state holder circuit through micro NOC 809. In operation 5, LCM AXI-MM target bridge 823 returns a write response B. In operation 6, the readback AXI-MM initiator receives the write response B indicating that LCM circuit 810 is ready for a readback operation of the first DUT state holder circuit.

Operations 7-12 described below can occur multiple times if the commands are sequenced. In operation 7, the readback data protocol AXI-MM initiator (e.g., in the fabric facing interface) sends a read request AR to the LCM AXI-MM target bridge 823 with ARBUSRT set to FIXED. In operation 8, the LCM AXI-MM target bridge 823 receives the read request AR. In operation 9, LCM circuit 810 performs a readback operation to the first DUT state holder circuit (e.g., one of memory circuits 831-832) through micro NOC 809. In operation 10, the LCM AXI-MM target bridge 823 returns a read response R. In operation 11, the readback data protocol AXI-MM initiator receives the read response R. In operation 12, readback data protocol AXI-MM initiator writes the first DUT state holder circuit data on a NOC interface or a direct input/output/transceiver interface.

In operation 13, after the readback data protocol AXI-MM initiator indicates completion of the command, the readback logic circuit sends a readback command AXI-MM initiator write request AW/W to LCM circuit 810 to initiate a readback operation of a second DUT state holder circuit, such as for example, a lookup table random access memory (LUTRAM) in fabric region 103. In operation 14, the LCM AXI-MM target bridge 823 receives the write request AW/W. In operation 15, LCM circuit 810 interprets the command in the write data WDATA and begins coordination of readback of the second DUT state holder circuit through micro NOC 809. In operation 16, the LCM AXI-MM target bridge 823 returns a write response B. In operation 17, the readback AXI-MM initiator receives the write response B indicating that the LCM circuit 810 is ready for a readback operation of the second DUT state holder circuit.

Operations 18-23 described below can occur multiple times if commands are sequenced. In operation 18, the readback data protocol AXI-MM initiator sends a read request AR to the LCM AXI-MM target bridge 823. In operation 19, the LCM AXI-MM target bridge 823 receives the read request AR. In operation 20, LCM circuit 810 performs a readback operation of the second DUT state holder circuit (e.g., one of memory circuits 831-832) through the micro NOC 809. In operation 21, the LCM AXI-MM target bridge 823 returns a read response R. In operation 22, the readback data protocol AXI-MM initiator receives the read response R. In operation 23, the readback data protocol AXI-MM initiator writes the second DUT state holder circuit data on a NOC interface or on a direct input/output/transceiver interface.

In operation 24, after the readback data protocol AXI-MM initiator indicates completion of the command, the readback logic circuit sends a readback command AXI-MM initiator write request AW/W to LCM circuit 810 to initiate readback from a third DUT state holder circuit (e.g., an embedded random access memory (ERAM)) in fabric region 103. In operation 25, the LCM AXI-MM target bridge 823 receives the write request AW/W. In operation 26, LCM circuit 810 interprets the command in the write data WDATA and begins coordination of readback of the third DUT state holder circuit through the micro NOC 809. In operation 27, LCM AXI-MM target bridge 823 returns a write response B. In operation 28, the readback AXI-MM initiator receives the write response B indicating that LCM circuit 810 is ready for a readback of the third DUT state holder circuit.

Operations 29-35 described below can occur multiple times if commands are sequenced. In operation 29, the readback data protocol AXI-MM initiator sends a read request AR to LCM AXI-MM target bridge 823 with ARBUSRT set to FIXED. In operation 30, LCM AXI-MM target bridge 823 receives the read request AR. In operation 31, LCM circuit 810 performs a readback operation of the third DUT state holder circuit (e.g., one of memory circuits 831-832) through the micro NOC 809. In operation 32, LCM AXI-MM target bridge 823 returns a read response R. In operation 33, the readback data protocol AXI-MM initiator receives the read response R. In operation 34, the readback data protocol AXI-MM initiator writes the third DUT state holder circuit data on a NOC interface or a direct input/output/transceiver interface. In operation 35, the readback logic circuit then finishes after running the complete sequence.

According to a specific example for performing writeback operations in emulation mode, a writeback logic circuit uses a fabric region or micro NOC AXI-MM initiator to send individual commands to the LCM circuit targets that prepare for the coordination of writeback of three DUT state holder circuits (e.g., an ALM, a LUTRAM, and an ERAM) in an IC. A writeback data protocol AXI-MM initiator performs write operations to the target bridge 823. Commands for these write operations can be interleaved. AXI-MM responses are used as examples for flow control of the commands and writeback data movement.

An example of a process having 35 operations for performing writeback for a sector column during emulation mode in an IC is described below. The initiators of the writeback can be logic circuitry in fabric region 103 or micro NOC initiators. The writeback logic circuit can choose multiple initiators to improve performance.

In operation 1, a user triggers a writeback operation using the writeback logic circuit. Operations 2-34 described below can occur multiple times with the ability to change the ordering of the writeback operations to the DUT state holder circuits, e.g., ALM FF, LUTRAM, and ERAM. In operation 2, the writeback logic circuit transmits a writeback command AXI-MM initiator write request AW/W to LCM circuit 810 to initiate a writeback to a first DUT state holder circuit, such as an adaptive logic module (ALM) flip-flop (FF), in fabric region 103. In operation 3, LCM AXI-MM target bridge 823 receives the write request AW/W. In operation 4, LCM circuit 810 interprets the command in the write data WDATA and begins coordination of the writeback to the first DUT state holder circuit through micro NOC 809. In operation 5, LCM AXI-MM target bridge 823 returns a write response B. In operation 6, the writeback AXI-MM initiator receives the write response B indicating that LCM circuit 810 is ready for writeback to the first DUT state holder circuit.

Operations 7-12 described below can occur multiple times if the commands are sequenced. In operation 7, the writeback data protocol AXI-MM initiator (e.g., in the fabric facing interface) reads data from the first DUT state holder circuit on a NOC interface or a direct input/output/transceiver interface. In operation 8, the writeback data protocol AXI-MM initiator sends a write request AW/W to the LCM target bridge 823 with ARBUSRT set to FIXED. In operation 9, LCM target bridge 823 receives the write request AW/W. In operation 10, LCM circuit 810 performs a writeback operation to the first DUT state holder circuit (e.g., one of memory circuits 831 or 832) through micro NOC 809. In operation 11, LCM target bridge 823 returns a write response B. In operation 12, the writeback data protocol AXI-MM initiator receives the write response B.

In operation 13, after the writeback data protocol AXI-MM initiator indicates completion of the command, the writeback logic circuit sends a writeback command AXI-MM initiator write request AW/W to LCM circuit 810 to initiate a writeback operation to a second DUT state holder circuit, e.g., a lookup table random access memory (LUTRAM), in fabric region 103. In operation 14, LCM target bridge 823 receives the write request AW/W. In operation 15, LCM circuit 810 interprets the command in the write data WDATA and begins coordination of the writeback operation to the second DUT state holder circuit through micro NOC 809. In operation 16, LCM target bridge 823 returns a write response B. In operation 17, the writeback AXI-MM initiator receives the write response B indicating that LCM circuit 810 is ready for writeback to the second DUT state holder circuit.

Operations 18-23 described below can occur multiple times if commands are sequenced. In operation 18, the writeback data protocol AXI-MM initiator (e.g., in the fabric facing interface) reads data from the second DUT state holder circuit on a NOC interface or a direct input/output/transceiver interface. In operation 19, the writeback data protocol AXI-MM initiator sends a write request AW/W to LCM target bridge 823 with ARBUSRT set to FIXED. In operation 20, LCM target bridge 823 receives the write request AW/W. In operation 21, LCM circuit 810 performs a writeback operation to the second DUT state holder circuit (e.g., one of memory circuits 831 or 832) through the micro NOC 809. In operation 22, LCM target bridge 823 returns a write response B. In operation 23, the writeback data protocol AXI-MM initiator receives the write response B.

In operation 24, after the writeback data protocol AXI-MM initiator indicates completion of the command, the writeback logic circuit sends a writeback command AXI-MM initiator write request AW/W to LCM circuit 810 to initiate a writeback operation to a third DUT state holder circuit, e.g., an embedded random access memory (ERAM), in fabric region 103. In operation 25, LCM target bridge 823 receives the write request AW/W. In operation 26, LCM circuit 810 interprets the command in the write data WDATA and begins coordination of the writeback operation to the third DUT state holder circuit through the micro NOC 809. In operation 27, LCM target bridge 823 returns a write response B. In operation 28, the writeback AXI-MM initiator receives the write response B indicating that the LCM circuit 810 is ready for a writeback operation to the third DUT state holder circuit.

Operations 29-35 described below can occur multiple times if commands are sequenced. In operation 29, the writeback data protocol AXI-MM initiator reads the third DUT state holder circuit data on a NOC interface or a direct input/output/transceiver interface. In operation 30, the writeback data protocol AXI-MM initiator sends a write request AW/W to LCM target bridge 823 with ARBUSRT set to FIXED. In operation 31, LCM target bridge 823 receives the write request AW/W. In operation 32, LCM circuit 810 performs a writeback operation to the third DUT state holder circuit (e.g., one of memory circuits 831 or 832) through the micro NOC 809. In operation 33, LCM target bridge 823 returns a write response B. In operation 34, the writeback data protocol AXI-MM initiator receives the write response B. In operation 35, the writeback logic circuit then finishes after running the complete sequence.

FIG. 9 is a diagram of an illustrative example of a configurable integrated circuit (IC) 900. Configurable IC 900 is an example of an IC that can include any of the circuits and/or perform any of the operations disclosed herein with respect to FIGS. 1-8. As shown in FIG. 9, the configurable integrated circuit 900 includes a two-dimensional array of configurable logic circuit blocks, including logic array blocks (LABs) 910 and other configurable logic circuit blocks, such as random access memory (RAM) blocks 930 and digital signal processing (DSP) blocks 920, for example. Configurable logic circuit blocks, such as LABs 910, can include smaller configurable logic circuits (e.g., configurable logic elements, configurable logic blocks, or adaptive logic modules (ALMs)) that receive input signals and perform custom functions on the input signals to produce output signals. The LABs 910, DSP blocks 920, and RAM blocks 930 can be located in a fabric region of the IC 900 and can be configured to perform any custom user functions. For example, LABs 910, DSP blocks 920, and RAM blocks 930 can be configured as an accelerator circuit.

The configurable integrated circuit 900 also includes programmable interconnect circuitry in the form of vertical routing channels 940 (i.e., interconnects formed along a vertical axis of configurable integrated circuit 900) and horizontal routing channels 950 (i.e., interconnects formed along a horizontal axis of configurable integrated circuit 900), each routing channel including at least one track to route at least one wire. One or more of the routing channels 940 and/or 950 can be part of a network-on-chip (NOC) having router circuits.

In addition, the configurable integrated circuit 900 has input/output elements (IOEs) 902 for driving signals off of configurable integrated circuit 900 and for receiving signals from other devices. Input/output elements 902 can include parallel input/output circuitry, serial data transceiver circuitry, differential receiver and transmitter circuitry, or other circuitry used to connect one integrated circuit to another integrated circuit. Input/output elements 902 can include general purpose input/output (GPIO) circuitry (e.g., on the top and bottoms edges of IC 900), high-speed input/output (HSIO) circuitry (e.g., on the left edge of IC 900), and on-package input/output (OPIOs) circuitry (e.g., on the right edge of IC 900).

As shown, input/output elements 902 can be located around the periphery of the IC. If desired, the configurable integrated circuit 900 can have input/output elements 902 arranged in different ways. For example, input/output elements 902 can form one or more columns of input/output elements that can be located anywhere on the configurable integrated circuit 900 (e.g., distributed evenly across the width of the configurable integrated circuit). If desired, input/output elements 902 can form one or more rows of input/output elements (e.g., distributed across the height of the configurable integrated circuit). Alternatively, input/output elements 902 can form islands of input/output elements that can be distributed over the surface of the configurable integrated circuit 900 or clustered in selected areas.

Note that other routing topologies, besides the topology of the interconnect circuitry depicted in FIG. 9, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 900, fractional global wires such as wires that span part of configurable integrated circuit 900, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 900 can also contain programmable memory elements. The memory elements can be loaded with configuration data (also called programming data) using input/output elements (IOEs) 902 during configuration mode. Once loaded with configuration data, the memory elements each provide a corresponding static control signal that controls the operation of an associated functional block (e.g., LABs 910, DSP 920, RAM 930, or input/output elements 902). The function blocks (e.g., LABs 910, DSP 920, RAM 930, or input/output elements 902) receive user data, generate user data, and transmit user data to other functional blocks in the IC and to external devices during the user mode to implement the functions of a circuit design for IC 900.

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 900 can include configuration memory that is organized in sectors, whereby a sector can include the configuration bits that specify the function and/or interconnections of the subcomponents and wires in or crossing that sector. Each sector can include separate data and address registers.

The configurable IC 900 of FIG. 9 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

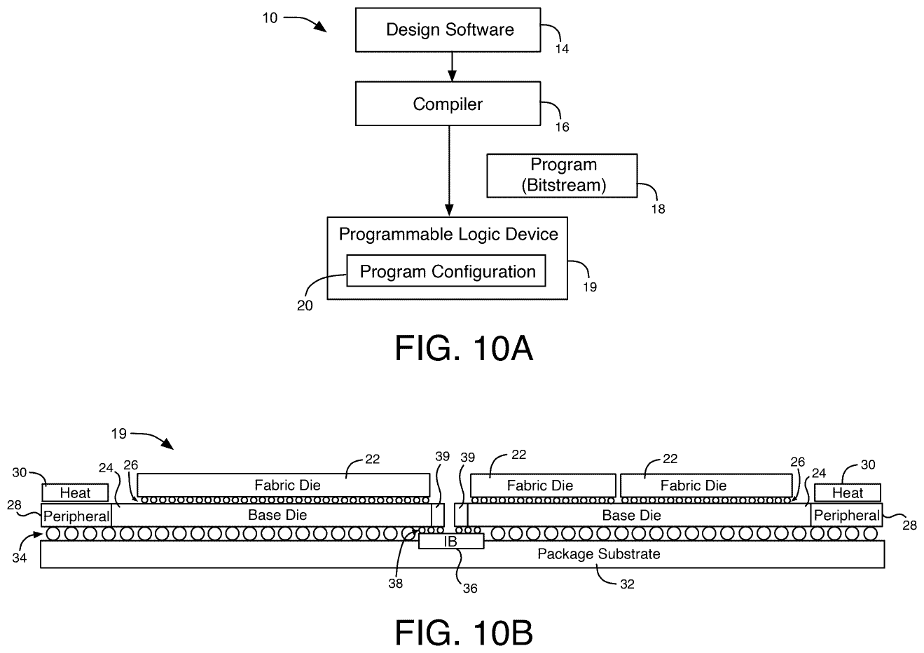

FIG. 10A illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 10B, but many others can be used, and it should be understood that this disclosure is intended to encompass any suitable programmable logic device where programmable logic fabric and fabric support circuitry are at least partially separated on different integrated circuit die.

FIG. 10B is a diagram that depicts an example of the programmable logic device 19 that includes three fabric die 22 and two base die 24 that are connected to one another via microbumps 26. In the example of FIG. 10B, at least some of the programmable logic fabric of the programmable logic device 19 is in the three fabric die 22, and at least some of the fabric support circuitry that operates the programmable logic fabric is in the two base die 24. For example, some of the circuitry of configurable IC 900 shown in FIG. 9 (e.g., LABs 910, DSP 920, and RAM 930) can be located in the fabric die 22 and some of the circuitry of IC 900 (e.g., input/output elements 902) can be located in the base die 24.

Although the fabric die 22 and base die 24 appear in a one-to-one relationship or a two-to-one relationship in FIG. 10B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 10B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

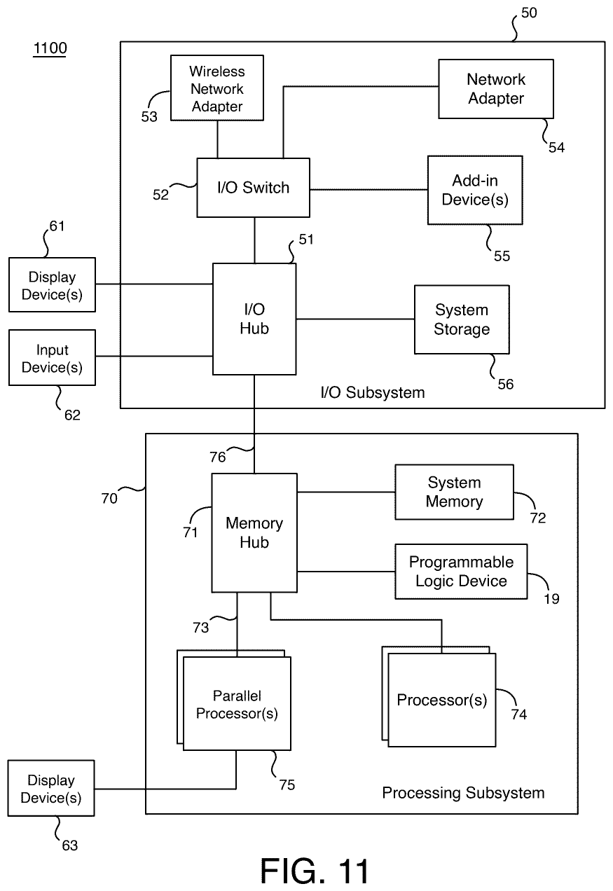

FIG. 11 is a block diagram illustrating a computing system 1100 configured to implement one or more aspects of the embodiments described herein. The computing system 1100 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 1100 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 1100. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 1100 can include other components not shown in FIG. 11, including other port connections, optical storage drives, video capture devices, and the like, that can also be connected to the I/O hub 51. Communication paths interconnecting the various components in FIG. 11 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 1100 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 1100 can be integrated into a single package to form a system in package (SIP) configuration. In one embodiment, at least a portion of the components of the computing system 1100 can be integrated into a multi-chip module (MCM), which can be interconnected with other multi-chip modules into a modular computing system.

The computing system 1100 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 1100. For example, any number of add-in cards or peripherals can be supported, or some components can be eliminated. Furthermore, some architectures can use different terminology for components similar to those illustrated in FIG. 11. For example, the memory hub 71 can be referred to as a Northbridge in some architectures, while the I/O hub 51 can be referred to as a Southbridge.

Additional examples are now described. Example 1 is an integrated circuit comprising: first logic circuits in a fabric region of the integrated circuit; and a first network-on-chip in the fabric region, wherein the first network-on-chip is configurable to transmit at least two of first user data, first configuration data, and first emulation data to the first logic circuits.

In Example 2, the integrated circuit of Example 1 further comprises: a second network-on-chip that traverses the fabric region, wherein the second network-on-chip is configurable to transmit at least two of second user data, second configuration data, and second emulation data to second logic circuits in the fabric region.

In Example 3, the integrated circuit of Example 2, wherein the second network-on-chip is configurable to transmit third user data and third emulation data from the second logic circuits.

In Example 4, the integrated circuit of any one of Examples 1-3 further comprises: a security controller circuit that performs security functions on the first configuration data and on the first emulation data.

In Example 5, the integrated circuit of any one of Examples 1-4, wherein the first network-on-chip is configurable to exchange the first configuration data for partial reconfiguration of the first logic circuits.

In Example 6, the integrated circuit of any one of Examples 1-5, wherein the first network-on-chip is configurable to exchange the first emulation data for emulation of the integrated circuit using the first logic circuits.

In Example 7, the integrated circuit of any one of Examples 1-6, wherein first network-on-chip comprises configuration manager circuits that are configurable to perform configuration of the first logic circuits with the first configuration data and emulation using the first logic circuits with the first emulation data.

In Example 8, the integrated circuit of any one of Examples 1-7 further comprises: a local configuration manager circuit that intercepts the first configuration data and the first emulation data to determine destinations for the first configuration data and the first emulation data.

In Example 9, the integrated circuit of any one of Examples 1-8, wherein the first network-on-chip comprises controller circuits and busses coupled between the controller circuits.

Example 10 is a method for transmission in an integrated circuit, the method comprising: receiving at least two of first user data, first configuration data, and first emulation data at a first network-on-chip in a fabric region of the integrated circuit; and transmitting the at least two of the first user data, the first configuration data, and the first emulation data through the first network-on-chip to first logic circuits in the fabric region.

In Example 11, the method of Example 10 further comprises: receiving at least two of second user data, second configuration data, and second emulation data at a second network-on-chip in the fabric region of the integrated circuit; and transmitting the at least two of the second user data, the second configuration data, and the second emulation data through the second network-on-chip to second logic circuits in the fabric region.

In Example 12, the method of any one of Examples 10-11, wherein transmitting the at least two of the first user data, the first configuration data, and the first emulation data through the first network-on-chip to the first logic circuits further comprises: transmitting the first configuration data and the first emulation data between a first configuration manager circuit in the integrated circuit through the first network-on-chip and a second configuration manger circuit in the first network-on-chip.

In Example 13, the method of any one of Examples 10-12 further comprises: configuring the first network-on-chip to exchange the first user data with the first logic circuits during a user mode of the integrated circuit.

In Example 14, the method of any one of Examples 10-13 further comprises: configuring the first network-on-chip to exchange the first configuration data for partial reconfiguration of the first logic circuits.

In Example 15, the method of any one of Examples 10-14 further comprises: configuring the first network-on-chip to exchange the first emulation data for operations for emulation using the first logic circuits.

Example 16 is an integrated circuit comprising: logic circuits in a region of the integrated circuit; and a network-on-chip in the region of the integrated circuit, wherein the network-on-chip is configurable to exchange at least two of user data, configuration data, and emulation data with the logic circuits.

In Example 17, the integrated circuit of Example 16, wherein the network-on-chip is configurable to transmit the user data to and from the logic circuits during a user mode of the integrated circuit.

In Example 18, the integrated circuit of any one of Examples 16-17, wherein the network-on-chip is configurable to transmit the configuration data to the logic circuits for configuring the logic circuits during a configuration mode of the integrated circuit.

In Example 19, the integrated circuit of any one of Examples 16-18, wherein the network-on-chip is configurable to transmit the emulation data to and from the logic circuits during an emulation mode of the integrated circuit.

In Example 20, the integrated circuit of any one of Examples 16-19, wherein the network-on-chip is configurable to transmit the configuration data to the logic circuits for partial reconfiguration of the logic circuits during a partial reconfiguration mode of the integrated circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
first logic circuits in a fabric region of the integrated circuit; and
a first network-on-chip in the fabric region,
wherein the first network-on-chip is configurable to transmit at least two of first user data, first configuration data, and first emulation data to the first logic circuits.

2. The integrated circuit of claim 1 further comprising:
a second network-on-chip that traverses the fabric region, wherein the second network-on-chip is configurable to transmit at least two of second user data, second configuration data, and second emulation data to second logic circuits in the fabric region.

3. The integrated circuit of claim 2, wherein the second network-on-chip is configurable to transmit third user data and third emulation data from the second logic circuits.

4. The integrated circuit of claim 1 further comprising:
a security controller circuit that performs security functions on the first configuration data and on the first emulation data.

5. The integrated circuit of claim 1, wherein the first network-on-chip is configurable to exchange the first configuration data for partial reconfiguration of the first logic circuits.

6. The integrated circuit of claim 1, wherein the first network-on-chip is configurable to exchange the first emulation data for emulation of the integrated circuit using the first logic circuits.

7. The integrated circuit of claim 1, wherein first network-on-chip comprises configuration manager circuits that are configurable to perform configuration of the first logic circuits with the first configuration data and emulation using the first logic circuits with the first emulation data.

8. The integrated circuit of claim 1 further comprising:
a local configuration manager circuit that intercepts the first configuration data and the first emulation data to determine destinations for the first configuration data and the first emulation data.

9. The integrated circuit of claim 1, wherein the first network-on-chip comprises controller circuits and busses coupled between the controller circuits.

10. A method for transmission in an integrated circuit, the method comprising:
receiving at least two of first user data, first configuration data, and first emulation data at a first network-on-chip in a fabric region of the integrated circuit; and
transmitting the at least two of the first user data, the first configuration data, and the first emulation data through the first network-on-chip to first logic circuits in the fabric region.

11. The method of claim 10 further comprising:
receiving at least two of second user data, second configuration data, and second emulation data at a second network-on-chip in the fabric region of the integrated circuit; and
transmitting the at least two of the second user data, the second configuration data, and the second emulation data through the second network-on-chip to second logic circuits in the fabric region.

12. The method of claim 10, wherein transmitting the at least two of the first user data, the first configuration data, and the first emulation data through the first network-on-chip to the first logic circuits further comprises:
transmitting the first configuration data and the first emulation data between a first configuration manager circuit in the integrated circuit through the first network-on-chip and a second configuration manger circuit in the first network-on-chip.

13. The method of claim 10 further comprising:
configuring the first network-on-chip to exchange the first user data with the first logic circuits during a user mode of the integrated circuit.

14. The method of claim 10 further comprising:
configuring the first network-on-chip to exchange the first configuration data for partial reconfiguration of the first logic circuits.

15. The method of claim 10 further comprising:
configuring the first network-on-chip to exchange the first emulation data for operations for emulation using the first logic circuits.

16. An integrated circuit comprising:
logic circuits in a region of the integrated circuit; and
a network-on-chip in the region of the integrated circuit,
wherein the network-on-chip is configurable to exchange at least two of user data, configuration data, and emulation data with the logic circuits.

17. The integrated circuit of claim 16, wherein the network-on-chip is configurable to transmit the user data to and from the logic circuits during a user mode of the integrated circuit.

18. The integrated circuit of claim 16, wherein the network-on-chip is configurable to transmit the configuration data to the logic circuits for configuring the logic circuits during a configuration mode of the integrated circuit.

19. The integrated circuit of claim 16, wherein the network-on-chip is configurable to transmit the emulation data to and from the logic circuits during an emulation mode of the integrated circuit.

20. The integrated circuit of claim 16, wherein the network-on-chip is configurable to transmit the configuration data to the logic circuits for partial reconfiguration of the logic circuits during a partial reconfiguration mode of the integrated circuit.
